(19) United States
(12) Patent Application Publication
(10) Pub. No.: US 2020/0176355 A1
(43) Pub. Date: Jun. 4, 2020

(54) SUBSTRATE EMBEDDED HEAT PIPE

(71) Applicant: Intel Corporation, Santa Clara, CA (US)

(72) Inventors: Robert A. May, Chandler, AZ (US); Kristof Darmawikarta, Chandler, AZ (US); Rahul Jain, Gilbert, AZ (US); Lilia May, Chandler, AZ (US); Maroun Moussallem, Chandler, AZ (US); Prithwish Chatterjee, Tempe, AZ (US)

(73) Assignee: Intel Corporation, Santa Clara, CA (US)

(21) Appl. No.: 16/209,861

(22) Filed: Dec. 4, 2018

(51) Int. Cl. H01L 23/473; H01L 23/373; H05K 7/20

(52) U.S. Cl. CPC H01L 23/473; H01L 23/3735; H05K 7/20336; H05K 7/20318; H05K 7/20327; H05K 7/20309

(57) ABSTRACT

A semiconductor device package structure is provided, which includes a substrate, one or more dies coupled to the substrate, and a heat pipe device. In an example, the heat pipe device may include a conduit that is at least partially embedded within the substrate. The heat pipe device may have a first region coupled to the one or more dies. In an example, the conduit may include a first path for flow of vapor from the first region to an opposing second region. The conduit may further include a second path for flow of liquid from the second region to the first region.

### BACKGROUND

Integrated Circuit (IC) semiconductor device packages are decreasing in size, while becoming more powerful. This has provided a thermal challenge. For example, removing heat from a bottom surface of an IC die that is on a substrate can be challenging.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A schematically illustrates a cross-sectional view of a semiconductor device package structure that includes a heat pipe device embedded at least in part within a substrate, e.g., to cool a component coupled to the substrate, according to some embodiments.

FIG. 1B illustrates the semiconductor device package structure of FIG. 1A, with thermally conductive material between the component and the heat pipe device, according to some embodiments.

FIG. 2A illustrates a magnified view of the heat pipe device of FIG. 1A, according to some embodiments.

FIGS. 2B-2D illustrate various example stages of formation of porous material that may be used in a heat pipe device, according to some embodiments.

FIGS. 3A-3E illustrate various example locations and configurations of heat pipe devices, according to some embodiments.

FIGS. 4A, 4B, 4C, 4D, 4E, 4F, 4G, 4H, 4I, 4J, 4K, and 4L illustrate example processes for formation of the semiconductor device package structure of FIG. 1A, according to some embodiments.

FIGS. 5A, 5B, 5C, and 5D illustrate example processes for formation of the semiconductor device package structure of FIG. 1A, according to some embodiments.

FIG. 6 illustrates a flowchart depicting a method for forming a semiconductor device package structure that includes a heat pipe device embedded at least in part within a substrate, e.g., to cool a component coupled to the substrate, according to some embodiments.

FIG. 7 illustrates a computer system, a computing device or a SoC (System-on-Chip), where one or more components of the computing device are included in a semiconductor package that includes a heat pipe device embedded at least in part within a substrate, e.g., to cool a component that is coupled to (or embedded within) the substrate, according to some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” or “some embodiments” means that a particular feature, structure, function, or characteristic described in connection with the embodiment is included in at least one embodiment of the invention. Thus, the appearances of the phrase “in an embodiment” or “in one embodiment” or “some embodiments” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The terms “left,” “right,” “front,” “back,”, “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

It is pointed out that those elements of the figures having the same reference numbers (or names) as the elements of any other figure can operate or function in any manner similar to that described, but are not limited to such.

In an example, in a semiconductor package, one or more IC dies may be coupled to (or embedded within) a substrate. It may be a challenge to dissipate heat from the IC dies. To alleviate such thermal issues, in some embodiments, the package has a heat pipe device embedded, at least in part, within the substrate of the package. The heat pipe device includes a fluid conduit having a first end coupled to the die (e.g., to a surface of a die that is coupled to the substrate, or to any other appropriate surface of the die), and an opposing second end coupled to a heat sink.

The conduit of the heat pipe device is hermitically sealed by sidewalls (e.g., where the sidewalls may include metal, such as copper). The conduit having the sidewalls form a heat pipe that is at least in part embedded within the substrate.

A heat pipe is a closed system that utilizes evaporative cooling to move heat from a heat source (e.g., from a hot side coupled to the hot die) to a heat sink (e.g., to a cold side coupled to the heat sink). Heat transfer of the heat pipe device operates on phase transition principle. For example, the conduit may include porous material occupying a section of the conduit, and open space or passageway over another section of the conduit. The conduit further includes coolant fluid, which may be in liquid and/or vapor phase.

The liquid phase of the coolant fluid in contact with the hot side of the conduit may evaporate, thereby absorbing heat from the hot side. The resulting vapor phase of the coolant fluid travels along the open passageway of the conduit towards the cold side. Once the vapor phase of the coolant fluid reaches at or near the cold side, the vapor may condense back to the liquid phase, thereby releasing latent heat at the cold side. The liquid phase of the coolant fluid is then transported back to the hot side through the porous material, for example, by capillary action. Thus, in the heat pipe device, the change of phase of the coolant fluid between liquid and vapor aids in transfer of heat from the hot side to the cold side, thereby cooling the die. Other technical effects will be evident from the various embodiments and figures.

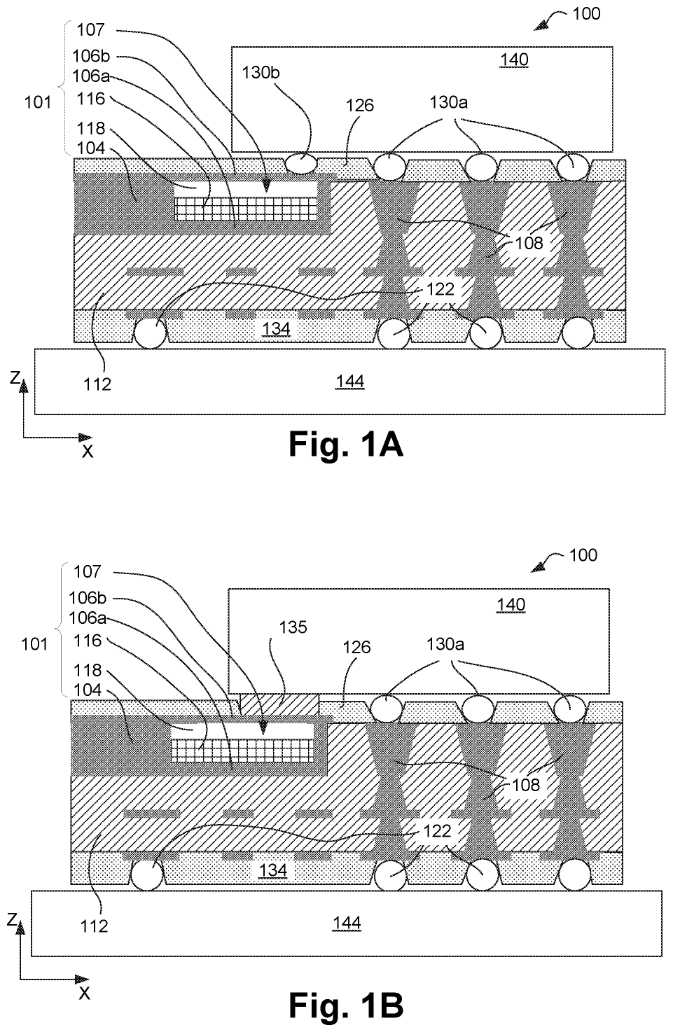

FIG. 1A schematically illustrates a cross-sectional view (e.g., along X-Z plane) of a semiconductor device package structure 100 (also referred to as package 100) that includes a heat pipe device 101 embedded at least in part within a substrate 112, according to some embodiments. Heat pipe device 101 may be operable to cool a component 140 coupled to the substrate 112, according to some embodiments.

The component 140 can be any electronic device or component that may be included in a semiconductor package, e.g., one or more IC dies, one or more chips, a processor, computer memory, platform controller hub, etc. In some embodiments, the component 140 is a discrete chip, a plurality of chips arranged at least in part in a stack over the substrate 112, or the like. The component 140 may include, or be a part of, a processor, memory, or application specific integrated circuit (ASIC), for example. Although merely one component 140 is illustrated, the package 100 may include any other appropriate number of components 140.

In some embodiments, the substrate 112 includes one or more layers 106 of dielectric material. A substrate discussed herein, such as the substrate 112, may electrically couple an electrical component (e.g., one or more IC dies) and a next-level component to which an IC package (e.g., a circuit board) is coupled. In an example, a substrate may include any suitable type of substrate capable of providing electrical communication between an IC die and an upper IC package coupled with a lower IC/die package. In an example, a substrate may include any suitable type of substrate capable of providing electrical communication between an upper IC package and a next-level component to which an IC package is coupled. A substrate may also provide structural support for a die. By way of example, in one embodiment, a substrate may comprise a multi-layer substrate—including alternating layers of a dielectric material and metal built-up around a core layer (either a dielectric core or a metal core). In another embodiment, a substrate may be a coreless multi-layer substrate. Other types of substrates and substrate materials may also be used (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases). In an example, a substrate is a cored or coreless package substrate, which may include epoxy resins, FR4, one or more semiconductor interposers (e.g., silicon), etc. A substrate may be formed of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, can be used in printed circuit boards (PCBs).

The component 140 is attached to the substrate 112 in any suitable configuration, such as a flip-chip configuration. The component 140 is coupled to the substrate 112 using a first plurality of interconnect structures 130a and a second one or more interconnect structures 130b, through a solder resist layer 126.

Elements referred to herein with a common reference label followed by a particular number or alphabet may be collectively referred to by the reference label alone. For example, multiple interconnect structures 130a may be collectively and generally referred to as interconnect structures 130a in plural and interconnect structure 130a in singular. Similarly, interconnect structures 130a, 130b may be collectively and generally referred to as interconnect structures 130 in plural, and interconnect structure 130 in singular.

The interconnect structures 130 for example, are bumps, bump pads, metal pillars (e.g., copper pillars), balls formed using metals, alloys, solderable material, or the like. For example, the interconnect structures 130 are bumps, balls, and/or solder comprising metals, alloys, solderable material, and/or the like.

In some embodiments, the interconnect structures 130b are for thermally coupling the heat pipe device 101 (also referred to as device 101) to the component 140. For example, the interconnect structures 130b may not transmit electrical signals to, or from, the component 140, and merely provide a thermally conductive path between the component 140 and the device 101. Thus, the interconnect structures 130b are electrically dead-ended on the component 140, such that the interconnect structures 130b are electrically isolated from various circuitries within the component 140. The interconnect structures 130b may also be referred to herein as thermal interconnect structures, or as thermal bumps. However, in some other examples, the interconnect structures 130b (and sidewalls 106 of the heat pipe device 101) may be part of a ground plane of the package 100. Thus, the interconnect structures 130b (and sidewalls 106 of the heat pipe device 101) are either electrically floating, or electrically grounded. Although merely one electrical interconnect structure 130b is illustrated in FIG. 1A, the package 100 may comprise any appropriate number of such thermal interconnect structures.

In some other examples, and contrary to the illustration of FIG. 1A, the thermal interconnect structures 130b may be absent from the package 100, and the component 140 may be thermally coupled to the device 101 by another appropriate manner, e.g., due to physical proximity, ambient air, thermally conductive underfill material (e.g., discussed with respect to FIG. 1B), solder resist layer 126, direct coupling via a thermal interface material, and/or the like.

Referring again to FIG. 1A, in some embodiments, the interconnect structures 130a are for electrically coupling the component 140 to the substrate 111. For example, the interconnect structures 130a transmit electrical signals between the component 140 and the substrate 112. The interconnect structures 130a may also be referred to herein as electrical interconnect structures. In an example, the interconnect structures 130a are electrically isolated from the interconnect structures 130b.

The package 100 includes a plurality of interconnect structures 108. The interconnect structures 108 are, for example, metallization levels embedded within various dielectric layers of the substrate 112. The interconnect structures 108 comprise metals, alloys, solderable material, or the like. In some embodiments, an individual build-up layer of the substrate 112 embeds an interconnect or metallization level (i.e., a routing layer) for trace routing within a dielectric layer for electrically insulating laterally adjacent traces as well as adjacent interconnect levels (overlying and/or underlying). The interconnect levels form the interconnect structures 108. Thus, the interconnect structures 108 may include conductive vias, solder, traces, metallization levels, routing layers, etc.

In some embodiments, the interconnect structures 108 are electrically coupled to the component 140. The interconnect structures 108 transmit signals to, and from, the component 140. For example, the interconnect structures 108 are to communicate signals between the component 140 and a circuit board 144, where the package 100 may be coupled to the circuit board 144. In some embodiments, the interconnect structures 108 are coupled to the circuit board 144 by interconnect structures 122, through a solder resist layer 126. The circuit board 144 may be a printed circuit board (PCB), a mother board, and/or the like.

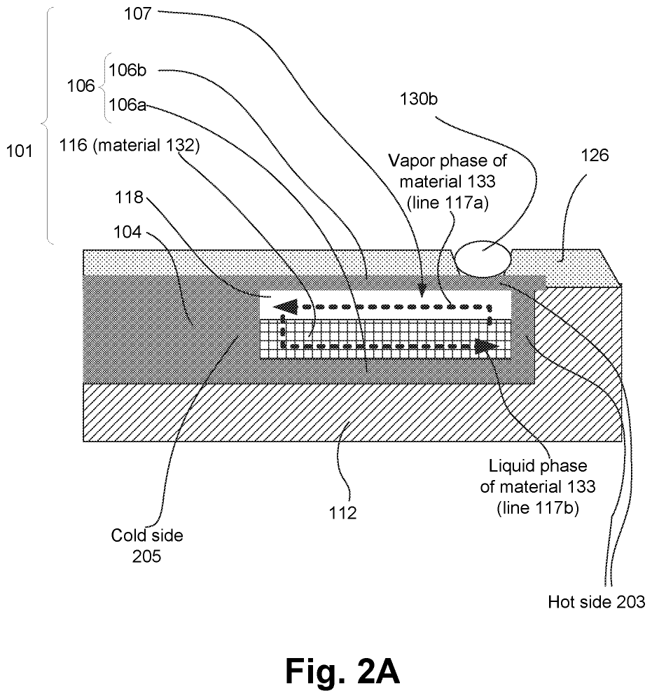

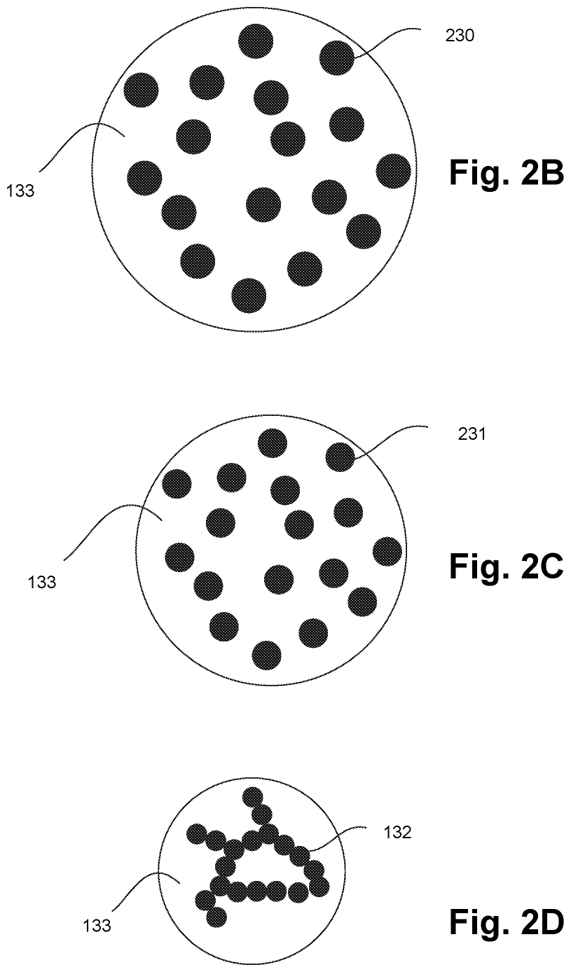

The package 100 includes the device 101. FIG. 2A illustrates a magnified view of the heat pipe device 101 of FIG. 1A, according to some embodiments. Referring to FIGS. 1A and 2A, the device 101 includes a cavity or conduit 107, which is at least partially embedded within the substrate 112. The conduit 107 is a hermitically sealed pipe, conduit or cavity, having sidewalls 106 (merely a top sidewall 106b and a bottom sidewall 106a of the conduit 107 are labelled in FIGS. 1A and 2A). Thus, the sidewalls 106 define the conduit 107.

One or more sides of the conduit 107, e.g., sides that are proximal to the component 140, are generally referred to as hot side 203. One or more sides of the conduit 107, which are away from the component 140, are generally referred to as a cold side 205. A heat sink or heat spreader 104 (also generally referred to as heat sink 104) is coupled to the cold side 205 of the conduit 107.

A first section 116 of the conduit 107 includes material 132 (the first section 116 and the material 132 are both symbolically illustrated using checkered field lines). The material 132 includes a plurality of pores (e.g., as discussed with respect to FIGS. 2B-2D herein later). For example, the material 132 includes porous material.

A second section 118 of the conduit 107 includes open space or open passageway. In an example, the second section 118 of the conduit 107 is over the first section 116.

The conduit 107 further comprises material 133 (also referred to herein as coolant material, coolant fluid, etc.), which may be either in a liquid phase or a vapor phase. For example, in FIG. 2A, a dotted line 117a illustrates an approximate direction of flow of the vapor phase of the material 133, and a dotted line 117b illustrates an approximate direction of flow of the liquid phase of the material 133. As illustrated in FIG. 2A, the vapor phase of the material 133 flows from the hot side 203 to the cold side 205 through the section 118, where the section 118 is the open space within the conduit 107. The liquid phase of the material 133 flows from the cold side 205 to the hot side 203 through the pores of the material 132, e.g., by capillary action.

The conduit 107 and the sidewalls 106 form a heat pipe that is, at least in part, embedded within the substrate 112. The heat pipe is a closed system that utilizes evaporative cooling to move heat from a heat source (e.g., from the hot side 203) to a heat sink (e.g., to the heat sink 104 coupled to the cold side 205). Heat transfer of the heat pipe device 101 may operate on one or both the following principals: thermal conductivity and phase transition. For example, the liquid phase of the material 133 in contact with the hot side 133 evaporates, e.g., thereby absorbing heat from the hot side 203. The resulting vapor phase of the material 133 travels along the open passageway (e.g., open section 118) towards the cold side 205. Once the vapor phase of the material 133 reaches at or near the cold side 205, the vapor condenses back to the liquid phase, thereby releasing latent heat at the cold side 205. The liquid phase of the material 133 is then transported back to the hot side 203 through the pores of the porous material 132 by capillary action.

Thus, in the device 101, the change of phase of the material 133 from between liquid and vapor aids in transfer of heat from the hot side 203 to the cold side 205. Accordingly, the material 133 is also referred to as coolant 133, as coolant material 133, as coolant fluid 133, etc. The heat transferred from the hot side 203 to the cold side 205 is dissipated from the cold side 205 by the heat sink 104. During operation, the hot side 203 is at a temperature that is equal to, or higher than, the temperature of the cold side 205.

In an example, an effectiveness of the heat pipe device 101 may be driven by thermal energy absorbed and/or released during coolant material phase change (e.g., from liquid to vapor, and/or from vapor to liquid). Latent heat of vaporization of material 133 at least in part dictates amount of thermal energy. The relatively large amount of heat energy required for evaporation (and released during condensation) enables the heat pipe of the device 101 to transfer heat from the hot side 203 to the cold side 205, thereby providing efficient thermal management in the package 100. In an example, the device 101 is a closed loop system (e.g., the conduit 107 is hermitically sealed), so that no user servicing is needed, which increases a reliability of the device 101.

In some embodiments, the sidewalls 106 of the device 101 include material that can hermitically seal the conduit 107. In some examples, the sidewalls 106 may also conduct heat from the hot side 203 to the cold side 205, which may further aid in transfer of heat (e.g., in addition to the transfer of heat due to phase transition of the material 133). Merely as an example, metal, such as copper (or any other appropriate type of material), may be used for the sidewalls 106.

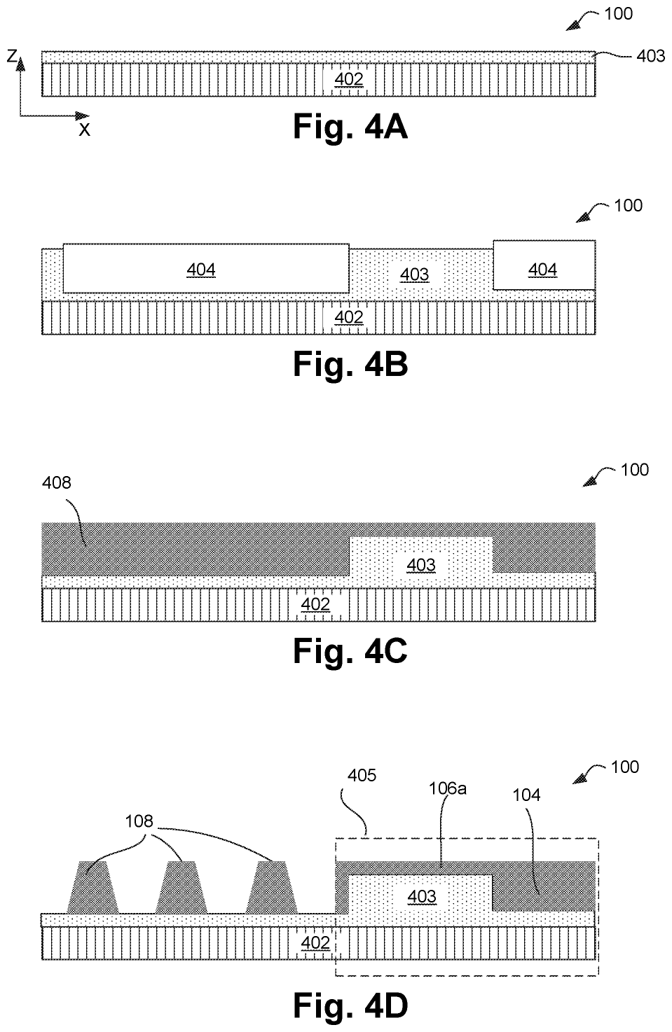

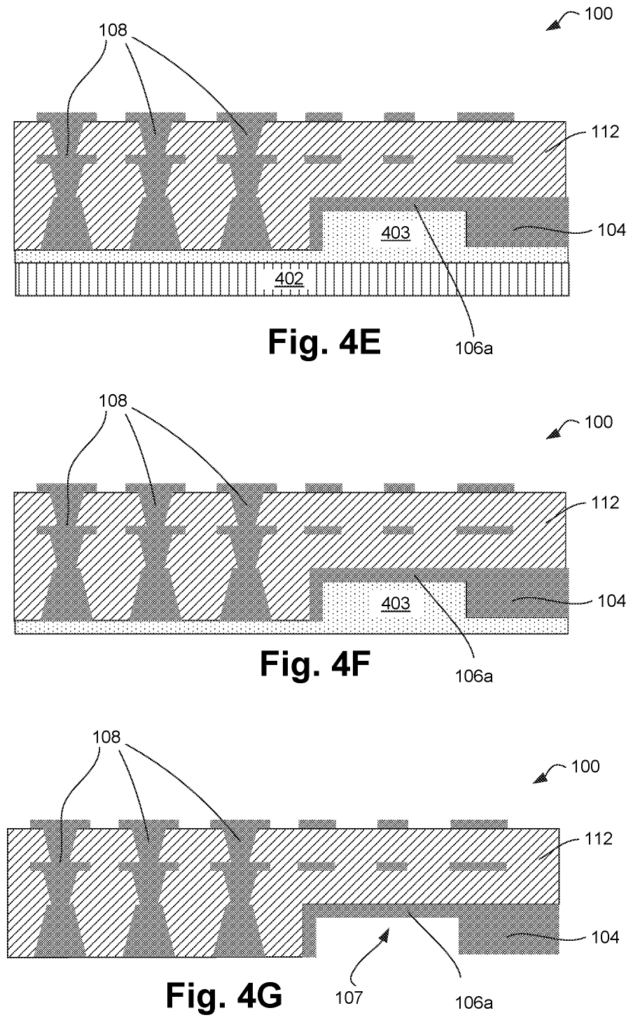

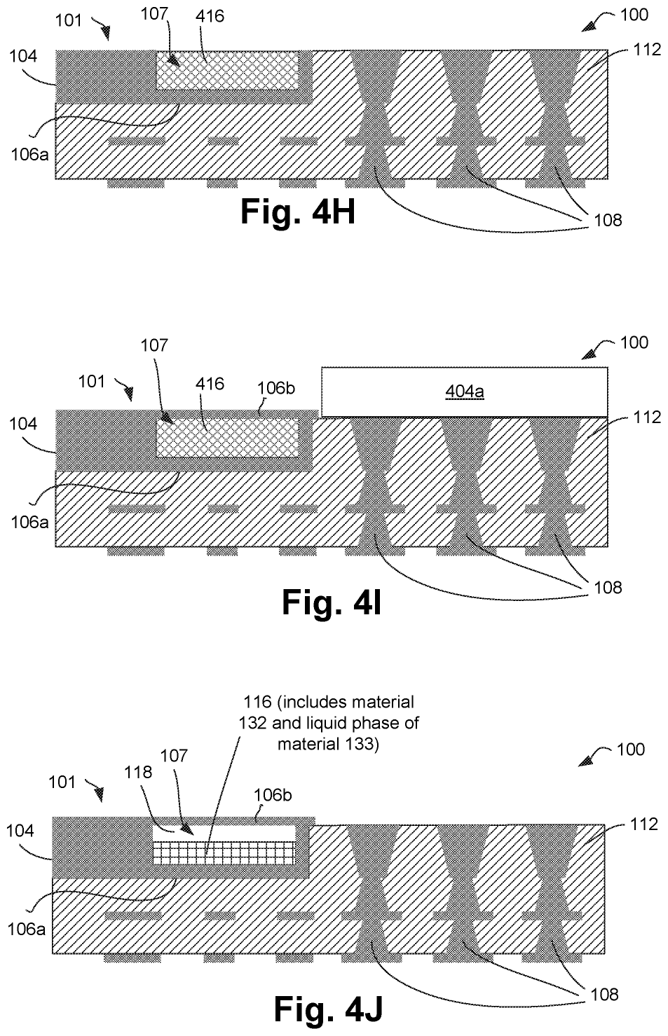

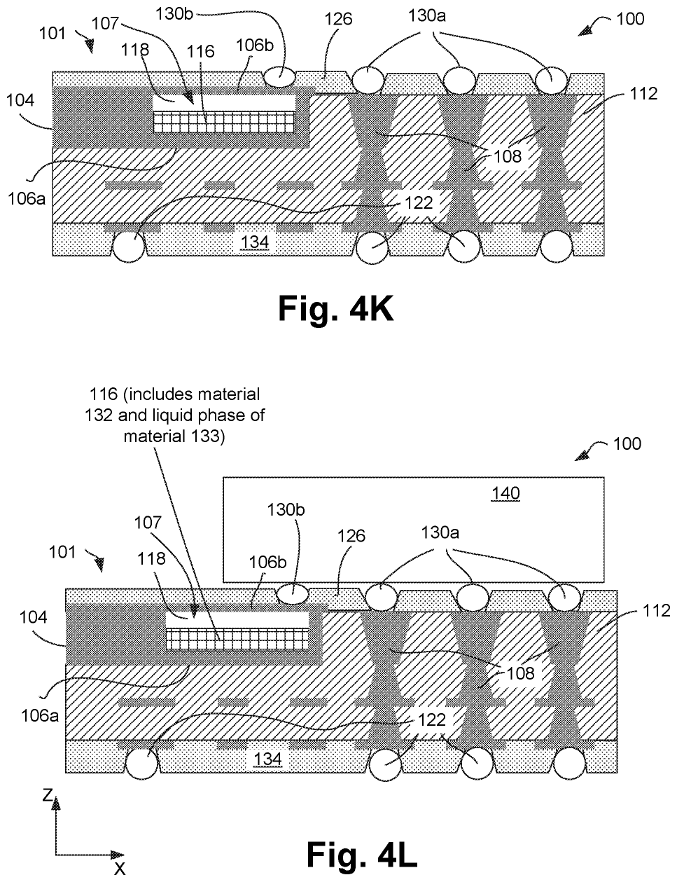

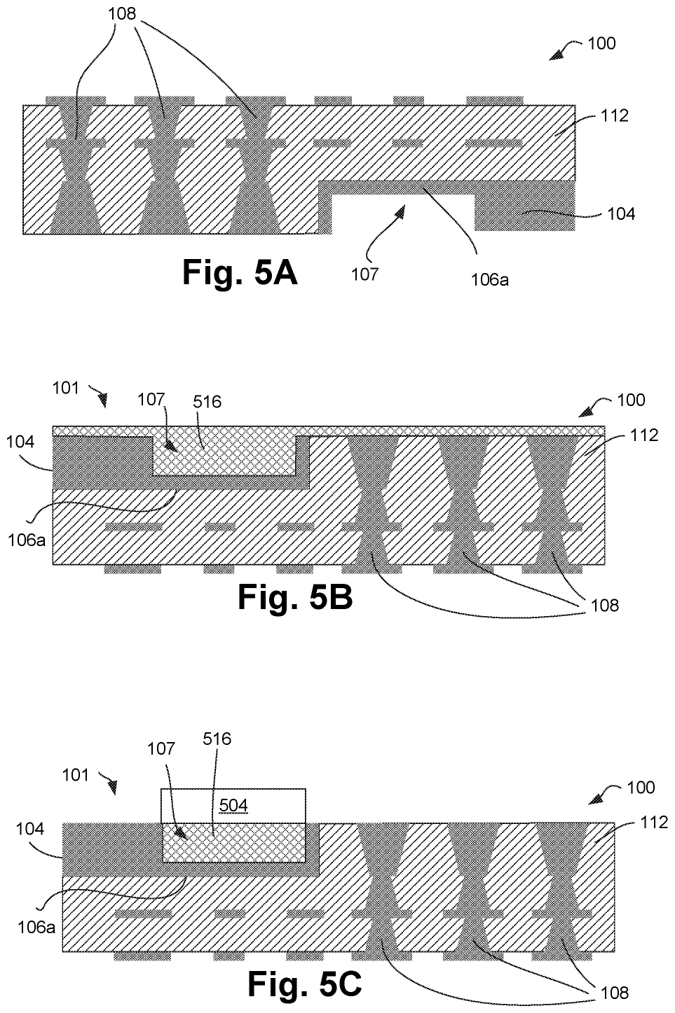

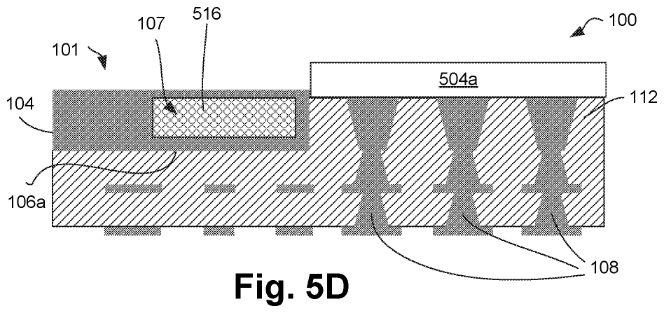

In an example, the sidewalls 106 include the same material as the material for the interconnect structures 108. In some examples, at least a section of the sidewalls 106 and at least a section of the interconnect structures 108 are formed using similar or same process (e.g., as discussed herein later with respect to FIGS. 4A-5C). Accordingly, in some examples, same material is used for the sidewalls 106 and the interconnect structures 108. In an example, as the material of the interconnect structures 108 is to be electrically conductive and as the material of the sidewalls 106 is to be thermally conductive, the material of the sidewalls 106 and the interconnect structures 108 may be thermally and electrically conductive, e.g., may be metal, such as copper.

In an example, a material of the heat sink 104 is same as the material of at least a section of the sidewalls 106. For example, the heat sink 104 and at least the section of the sidewalls 106 may be formed using the same process, and hence, the heat sink 104 and at least the section of the sidewalls 106 may include same material, e.g., metal, such as copper.

The heat pipe (e.g., which includes the conduit 107 having the sidewalls 106) is at least in part embedded within the substrate 112. The heat pipe is at least in part embedded within the substrate 112 such that, for example, at least some sections of the sidewalls 106 are in contact with the substrate 112 (e.g., in contact with dielectric layer(s) and/or interconnect layers of the substrate 112). In the example of FIG. 2A, the heat pipe is partially embedded within the substrate 112, e.g., such that a bottom section and a side section of the sidewalls 106 are in contact with the substrate 112. Merely as an example, a height of the sidewalls 106 (e.g., a height along the Z plane) may be substantially equal to a discrete number of package substrate levels (e.g., one package substrate level) of the substrate 112. In the example of FIG. 2A, the heat sink 104 is also embedded at least in part within the substrate 112 (e.g., a bottom section of the heat sink 104 is in contact with dielectric layer(s) of the substrate 112.

The coolant material 133 to be used for the device 101 may be based on an application of the package 100. For example, the selection of the material 133 may be based on an anticipated maximum temperature at the hot side 203, a desired amount of heat to be transferred, etc. For example, heat generated at the hot side 203 should be sufficient enough to cause the phase transition from liquid to vapor at or near the hot side. Thus, a boiling point of the coolant material 133 has to be selected appropriately for the device 101 to work properly. The amount of heat to be transferred may be based on the latent heat (e.g., with a unit of Joules per gram, or J/g) of the material 133. Table 1 below illustrates example fluid that may be used as the coolant material 133, along with a boiling point and latent heat.

TABLE 1

| Fluids that may be used as Material 133 | Latent Heat(J/g) | Boiling Point |
|---|---|---|
| Water | 2257 | 100° C. |
| Isopropyl Alcohol | 732.2 | 82.6 |
| Ethanol | 841 | 78 |
| Methanol | 1104 | 64.7 |
| | Property dependent on mixture | |
| Water/Alcohol mixture | ratios of water and alcohol | |
| Acetone | 538.9 | 56 |
| Diethyl Ether | 353 | 34 |

Any of the fluids (or a combination of one or more fluids) of table 1, or any other appropriate fluid, may be used as a coolant 133, e.g., based on an application of the package 100, an anticipated maximum temperature at the hot side 203, a desired amount of heat to be transferred, etc.

Numerous variations of the package 100 may be possible. For example, FIG. 1B illustrates the package 100 of FIG. 1A, with thermally conductive material 135 between the component 140 and the device 101, according to some embodiments. The package 100 in FIG. 1B is similar to the package 100 of FIG. 1A. However, in the package 100 of FIG. 1B, the thermally conductive interconnect structures 130b are replaced by thermally conductive material 135. In an example, the material 135 may be a thermally conductive underfill material. In an example, the material 135 may be a thermally conductive adhesive material, a thermally conductive paste, a thermally conductive grease, thermally conductive solder material, a thermal interface material (TIM), solder resist material, and/or the like. In an example, the material 135 may have higher thermal conductivity than the substrate 112 (e.g., may have higher thermal conductivity than the dielectric layers of the substrate 112).

Referring to FIGS. 1A, 1B, and 2A, in some examples, the material 132 may be “sol-gel” material formed using “sol-gel process.” In a sol-gel process, a “sol” (e.g., a colloidal solution) is initially formed, which then gradually evolves towards the formation of a gel-like diphasic system containing both a liquid phase and solid phase whose morphologies range from discrete particles to continuous polymer networks. The process involves conversion of monomers into a colloidal solution (sol) that acts as the precursor for an integrated network (or gel) of either discrete particles or network polymers.

The sol-gel material 132 is to deliver liquid coolant material 133 to the conduit 107. The sol-gel material 132 is to also to provide flow paths for liquid and/or vapor transport between hot and cold ends of the heat pipe device 101. For example, the liquid phase of the material 133 flows through the porous network due to liquid capillary action. Also, open passageway in the conduit 107 is used for transport of vapor phase of the material 133.

FIGS. 2B-2D illustrates various example stages of formation of the porous material 132 that may be used in a heat pipe device (e.g., heat pipe device 101 of the package 100 of FIGS. 1A-1B), according to some embodiments. FIG. 2B illustrates a “sol” or colloidal solution form 230 of the material 132. Also illustrated in FIG. 2B is the liquid coolant material 133. As illustrated in FIG. 2B, the uncured (e.g., prior to any curing) form 230 of the material 132 has a network of pores. In an example, the sol form of the material 132 in FIG. 2B may be in the form of a paste or colloidal solution.

The material 132 (e.g., including the forms 230, 231 of FIGS. 2B-2C) may include, merely as an example, any appropriate polymer, e.g., low molecular weight polymer. In an example, metal alkoxides may be used as precursors for the polymer. Thus, the material 132 in FIG. 2B may include polymers within a pre-cursor solution, where the pre-cursor solution may include metal alkoxides.

The sol form of FIG. 2B may be partially cured to produce a gel form 231 of the material 132, where the gel form 231 is illustrated in FIG. 2C. The gel form 231 may be a partially cured B-stage resin. The partial curing of the material from the sol form 230 of FIG. 2B to the gel form of FIG. 2C may result in shrinkage of volume, and accompanying shrinkage of the pore sizes. In an example, the sol form of the material 132 in FIG. 2B may be in the form of a laminate.

The gel form of FIG. 2C may be fully cured to produce the cured material 132 of FIG. 2D. The curing may further shrink the volume of the material 132, with accompanying shrinkage of the pore sizes.

In an example, a pore size of the cured material 132 in FIG. 2D may be controlled by controlling the gelling temperature profile (e.g., by controlling the temperature used for curing in FIGS. 2C and 2D), and may be used to form desired size for formation of porous scaffold within the material 132 for efficient transport of the liquid material 133 through capillary action.

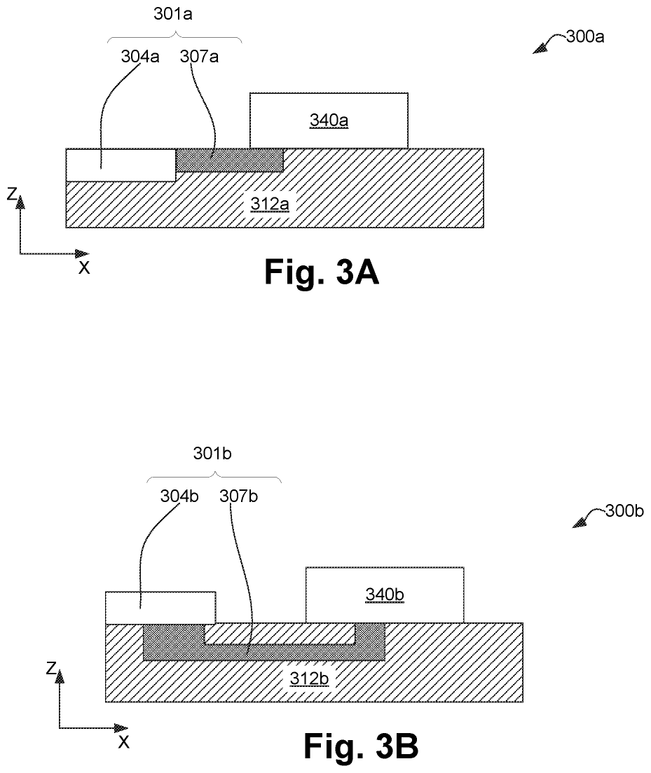

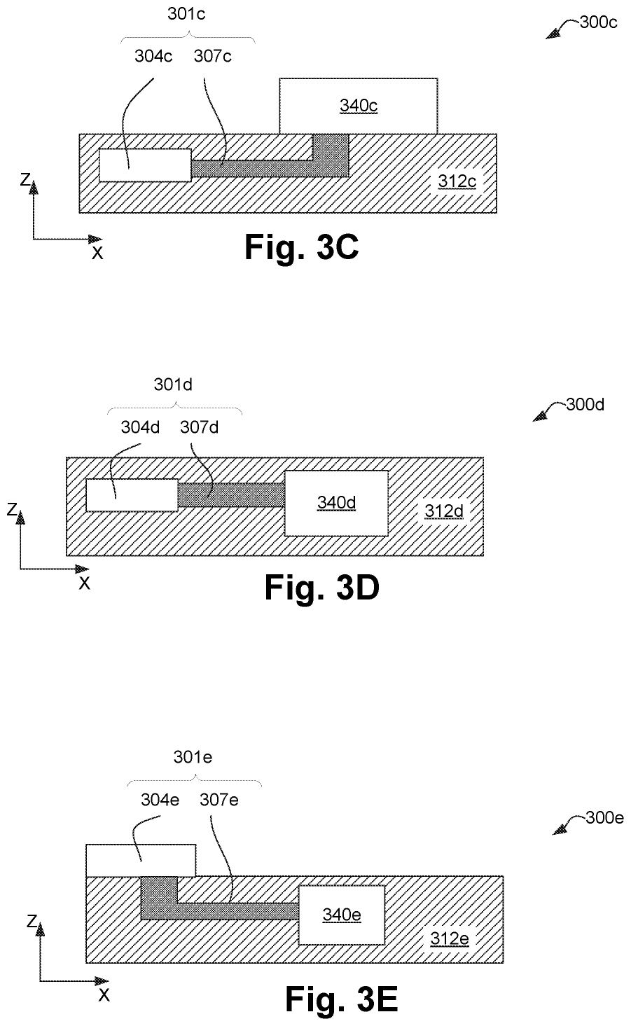

FIGS. 3A-3E illustrate various example locations and configurations of heat pipe devices, according to some embodiments. Referring to FIG. 3A, illustrated is a package 300a including a component 340a (e.g., which is similar to the component 140 of the package 100) coupled to a substrate 312a (e.g., which is similar to the substrate 112 of the package 100). Also illustrated is a heat pipe device 301a (also referred to as device 310a) that includes a conduit 307a and a heat sink 304a (the conduit 340a is illustrated using a simple box, without illustrating the elements within the conduit 340a). The conduit 307a and the heat sink 304a are at least in part similar to the conduit 107 and heat sink 104, respectively, of the package 100 of FIG. 1A. Not all components of the package 300a (e.g., various interconnect structures, circuit board, solder resist layers, etc.) are illustrated in FIG. 3A. In the embodiments of FIG. 3A, the component 340a is external to the substrate 312a, the conduit 307a is at least in part embedded within the substrate 312a, and the heat sink 304a is at least in part embedded within the substrate 312a. For example, a first side and a bottom side of sidewalls of the conduit 307a is in contact with the substrate 312a (e.g., in contact with dielectric layer(s) of the substrate 312a), as illustrated in FIG. 3A. Similarly, one or more sides of the heat sink 304a is in contact with the substrate 312a (e.g., in contact with dielectric layer(s) of the substrate 312a), as illustrated in FIG. 3A. In an example, top surfaces of the sidewalls of the conduit 307a and/or the heat sink 304a may be substantially flush with a top surface of the substrate 312a. In an example, top surfaces of the sidewalls of the conduit 307a and/or the heat sink 304a may be exposed through the top surface of the substrate 312a.

Referring to FIG. 3B, illustrated is a package 300b including a component 340b (e.g., which is at least in part similar to the component 140 of the package 100) coupled to a substrate 312b (e.g., which is at least in part similar to the substrate 112 of the package 100). Also illustrated is a heat pipe device 301b (also referred to as device 310b) that includes a conduit 307b and a heat sink 304b (the conduit 340b is illustrated using a simply box, without illustrating the elements within the conduit 340b). The conduit 307b and the heat sink 304b are at least in part similar to the conduit 107 and heat sink 104, respectively, of the package 100 of FIG. 1A. Not all components of the package 300b (e.g., various interconnect structures, circuit board, solder resist layers, etc.) are illustrated in FIG. 3B. In the embodiments of FIG. 3B, the component 340b is external to the substrate 312b, the conduit 307b is embedded within the substrate 312b, and the heat sink 304b is coupled to the substrate 312b.

For example, two or more sides of sidewalls of the conduit 307b are in contact with the substrate 312b (e.g., in contact with dielectric layer(s) of the substrate 312b), as illustrated in FIG. 3B. Similarly, at least one side of the heat sink 304b is in contact with the substrate 312b (e.g., in contact with dielectric layer(s) of the substrate 312b), as illustrated in FIG. 3B.

Referring to FIG. 3C, illustrated is a package 300c including a component 340c (e.g., which is at least in part similar to the component 140 of the package 100) coupled to a substrate 312c (e.g., which is at least in part similar to the substrate 112 of the package 100). Also illustrated is a heat pipe device 301c (also referred to as device 310c) that includes a conduit 307c and a heat sink 304c (the conduit 340c is illustrated using a simply box, without illustrating the elements within the conduit 340c). The conduit 307c and the heat sink 304c are at least in part similar to the conduit 107 and heat sink 104, respectively, of the package 100 of FIG. 1A. Not all components of the package 300c (e.g., various interconnect structures, circuit board, solder resist layers, etc.) are illustrated in FIG. 3C. In the embodiments of FIG. 3C, the component 340c is external to the substrate 312c, the conduit 307c is embedded within the substrate 312c, and the heat sink 304c is embedded within the substrate 312c.

For example, two or more sides of sidewalls of the conduit 307c are in contact with the substrate 312c (e.g., in contact with dielectric layer(s) of the substrate 312c), as illustrated in FIG. 3C. As an example, the conduit 307c may be encapsulated or surrounded by the substrate 312c. Similarly, two or more sides of the heat sink 304c is in contact with the substrate 312c (e.g., in contact with dielectric layer(s) of the substrate 312c), as illustrated in FIG. 3C. As an example, the heat sink 304c may be fully encapsulated or enclosed by the substrate 312c, e.g., no section of the heat sink 304c may be outside the substrate 312c.

Referring to FIG. 3D, illustrated is a package 300d including a component 340d (e.g., which is at least in part similar to the component 140 of the package 100) coupled to a substrate 312d (e.g., which is at least in part similar to the substrate 112 of the package 100). Also illustrated is a heat pipe device 301d (also referred to as device 310d) that includes a conduit 307d and a heat sink 304d (the conduit 340d is illustrated using a simple box, without illustrating the elements within the conduit 340d). The conduit 307d and the heat sink 304d are at least in part similar to the conduit 107 and heat sink 104, respectively, of the package 100 of FIG. 1A. Not all components of the package 300d (e.g., various interconnect structures, circuit board, solder resist layers, etc.) are illustrated in FIG. 3D. In the embodiments of FIG. 3D, the component 340d is embedded within the substrate 312d, the conduit 307d is embedded within the substrate 312d, and the heat sink 304d is embedded within the substrate 312d.

For example, two or more sides of sidewalls of the conduit 307d and two or more sides of the heat sink 340d are in contact with the substrate 312d (e.g., in contact with dielectric layer(s) of the substrate 312d), as illustrated in FIG. 3D. As an example, the conduit 307d and the heat sink 340d are encapsulated or surrounded by the substrate 312d. For example, no section of the heat sink 304d and/or the conduit 307d may be exposed outside the substrate 312d. The component 340d is embedded within the substrate 312d, e.g., such that two or more sides of the component 340d are in contact with the substrate 312d (e.g., in contact with dielectric layer(s) of the substrate 312d), as illustrated in FIG. 3D. As an example, the component 340d is encapsulated or surrounded by the substrate 312d, and no section of the component 340d may be exposed outside the substrate 312d.

In FIG. 3D, the conduit 307d and the component 340d are embedded (e.g., fully embedded) within the substrate 312d (e.g., fully encapsulated by the substrate 312d). In an example, at least a section of the conduit 307d and at least a section of the component 340d may be embedded within a same level of the substrate 312d. In another example, at least a section of the conduit 307d may be embedded within a first level of the substrate 312d, and at least a section of the component 340d may be embedded within a second level of the substrate 312d, where the first and second levels are different.

Referring to FIG. 3E, illustrated is a package 300e including a component 340e (e.g., which is at least in part similar to the component 140 of the package 100) coupled to a substrate 312e (e.g., which is at least in part similar to the substrate 112 of the package 100). Also illustrated is a heat pipe device 301e (also referred to as device 310e) that includes a conduit 307e and a heat sink 304e (the conduit 340e is illustrated using a simple box, without illustrating the elements within the conduit 340e). The conduit 307e and the heat sink 304e are at least in part similar to the conduit 107 and heat sink 104, respectively, of the package 100 of FIG. 1A. Not all components of the package 300e (e.g., various interconnect structures, circuit board, solder resist layers, etc.) are illustrated in FIG. 3E. In the embodiments of FIG. 3E, the component 340e is embedded within the substrate 312d, the conduit 307e is embedded within the substrate 312d, and the heat sink 304e is coupled to the substrate 312e.

For example, two or more sides of sidewalls of the conduit 307e are in contact with the substrate 312e (e.g., in contact with dielectric layer(s) of the substrate 312e), as illustrated in FIG. 3E. As an example, the conduit 307e are encapsulated or surrounded by the substrate 312e. The component 340e is embedded within the substrate 312e, e.g., such that two or more sides of the component 340e are in contact with the substrate 312e (e.g., in contact with dielectric layer(s) and/or routing layers of the substrate 312e), as illustrated in FIG. 3E. As an example, the component 340e is encapsulated or surrounded by the substrate 312e, e.g., similar to the component 340d of FIG. 3D.

In FIG. 3E, the conduit 307e and the component 340e are embedded (e.g., fully embedded) within the substrate 312e (e.g., fully encapsulated by the substrate 312e). In an example, at least a section of the conduit 307e and at least a section of the component 340e may be embedded within a same level of the substrate 312e. In another example, at least a section of the conduit 307e may be embedded within a first level of the substrate 312e, and at least a section of the component 340e may be embedded within a second level of the substrate 312e, where the first and second levels are different.

FIGS. 4A, 4B, 4C, 4D, 4E, 4F, 4G, 4H, 4I, 4J, 4K, and 4L illustrate example processes for formation of the semiconductor device package structure 100 (e.g., package 100) of FIG. 1A, according to some embodiments. For example, FIGS. 4A-4L are cross-sectional views of the package 100 evolving as example operations for formation of the package 100 are performed.

Referring to FIG. 4A, a carrier layer 402 is provided, where a sacrificial layer 403 is on a side of the carrier layer 402. The carrier layer 402 is to provide support for the package 100, as the package is being formed, and the carrier layer 402 is to be removed at a later stage during formation of the package 100. Any appropriate material may be used for the carrier layer 402 and the sacrificial layer 403. Merely as an example, the sacrificial layer 403 may include metal, such as nickel, titanium, etc. In an example, a top surface of the sacrificial layer 403 (where the top surface is opposite to a bottom surface of the sacrificial layer 403 that faces the carrier layer 402) is flat. In an example, the sacrificial layer 403 is coupled to the carrier layer 402 through an adhesive film (not illustrated in FIG. 4A).

Referring now to FIG. 4B, the sacrificial layer 403 is patterned (e.g., using dry film resist layer 404, or another appropriate resist layer), and material of the sacrificial layer 403 (e.g., nickel) is plated to the sacrificial layer 403, e.g., to increase dimensions of the sacrificial layer 403.

Referring now to FIG. 4C, the dry film resist layer 404 is removed and material 408 is plated over the sacrificial layer 403. During subsequent processing of the package, the material 408 is to form the sidewalls 106 of the device 101 and to form sections of the interconnect structures 108. Accordingly, in some examples, the material 408 may be thermally and electrically conductive, e.g., may be metal, such as copper.

Referring now to FIG. 4D, at least a section of the material 408 is patterned, e.g., to form portions of interconnect structures 108. The patterning of the section of material 408 may be performed using any appropriate process, e.g., laser drilling, etching, desmear, etc.

Another section of the material 408 (e.g., where a boundary of this section is illustrated using a dotted line 405) is not etched or patterned, and this section is to later form the sidewall 106a of the conduit 107 and the heat sink 104.

Referring now to FIG. 4E, layers of substrate 112 are deposited and the interconnect structures 108 are formed in situ with the substrate 112. Any appropriate process may be used to form the substrate 112 and the interconnect structures 108, e.g., semi-additive process of formation of the interconnect structures 108, laser drilling, etching, desemear, etc.

Referring now to FIG. 4F, the carrier layer 402 is removed from the package 100. Referring now to FIG. 4G, the sacrificial layer 403 is removed. For example, the sacrificial layer 403 is etched, with the sidewall 106a, the heat sink 104, and the interconnect structures 108 acting as etch stop. Removing the sacrificial layer 403 results in formation of the conduit 107 (e.g., with the sidewalls of the conduit 107 not being formed fully in FIG. 4G).

Referring now to FIG. 4H, material 416 is printed within the conduit 107, and partially cured. The material 416 deposited in the conduit 107 may be in the form of a paste, and the deposited material 416 may be partially cured to form a B-stage resin. The material 416 that is deposited in the conduit 107 may be in the form illustrated in FIG. 2B, e.g., in a sol form 230, and may include liquid coolant material 133. Partially curing the material 416 may result in the gel form, or B-stage form of the material 416, as illustrated in FIG. 4C.

Referring now to FIG. 4I, dry film resist layer 404a is formed (e.g., laminated) on the surface of the substrate 112 that is not occupied by the heat pipe device 101. Subsequently, appropriate material (e.g., copper) is plated on the device 101, e.g., to form the sidewall 106b of the conduit 107. Thus, in FIG. 4I, the conduit 107 is hermitically sealed by the sidewalls 106. The partially cured B stage resin material 416 provides support while the sidewall 106b is being plated.

Referring now to FIG. 4J, the dry film resist layer 404a is stripped and removed, and the material 416 is fully cured (e.g., by applying heat). Curing the material 416 results in formation of the material 132 and 133, e.g., similar to that of FIG. 2D.

For example, in FIG. 4J, the section 116 of the conduit 107 includes the porous material 132 and the liquid phase of the material 133. Due to the shrinkage during the curing process, the section 118 of the conduit 107 is formed, which includes open space or passageway.

Referring now to FIG. 4K, interconnect structures 130a, 130b, 122, solder resist layers 126, 134, etc. are formed using any appropriate process. Referring now to FIG. 4L, component 140 is coupled to the interconnect structures 130a, 130b, resulting in the package 100 of FIG. 1A (although the circuit board 144 of FIG. 1A is not illustrated in FIG. 4L).

FIGS. 5A, 5B, 5C, and 5D illustrate example processes for formation of the semiconductor device package structure 100 (e.g., package 100) of FIG. 1A, according to some embodiments. For example, FIGS. 5A-5D are cross-sectional views of the package 100 evolving as example operations for formation of the package 100 are performed.

Referring to FIG. 5A, the package 100 including the substrate 112, the interconnect structures 108, and sections of the device 101 (e.g., the sidewall 106a, conduit 107, and the heat pipe 104) are provided. The package 100 of FIG. 5A is similar to that of FIG. 4G, and the package 100 of FIG. 5A may be formed using the processes discussed with respect to FIGS. 4A-4G.

Referring to FIG. 5B, material 516 is laminated within the cavity 107. The material 516 laminated in the conduit 107 includes partially cured gel form of the sol-gel material 132 and the liquid coolant material 133, e.g., the form 231 of FIG. 2C.

Referring to FIG. 5C, resist layer 504 (e.g., which may be a dry film resist layer) is formed over the cavity 107, and the material 516 outside the cavity 107 is removed (e.g., using a dry etch process).

Referring now to FIG. 5D, resist layer 504 is removed, and resist layer 504a is formed (e.g., laminated) on the surface of the substrate 112 that is not occupied by the heat pipe device 101. Subsequently, appropriate material (e.g., copper) is plated on the device 101, e.g., to form the sidewall 106b of the conduit 107. Thus, in FIG. 5D, the conduit 107 is hermitically sealed by the sidewalls 106. The partially cured B stage laminated resin material 516 provides support while the sidewall 106b of the conduit 107 are being plated.

FIG. 5D is substantially similar to the illustration in FIG. 4I. The package 100 of FIG. 5D is then processed, e.g., as discussed with respect to FIGS. 4J-4L, to form the final package of FIG. 1A.

Thus, in FIGS. 4A-4L (e.g., specifically in FIG. 4H), the material 132, in the form of sol (e.g., a colloidal solution, prior to any curing) or paste (e.g., in the form illustrated in FIG. 2B) is printed in the cavity 107. In contrast, in FIGS. 5A-5D (e.g., specifically in FIG. 5B), the material 132, in the form of partially cured B-stage resin (e.g., in the form illustrated in FIG. 2C) is laminated in the cavity 107.

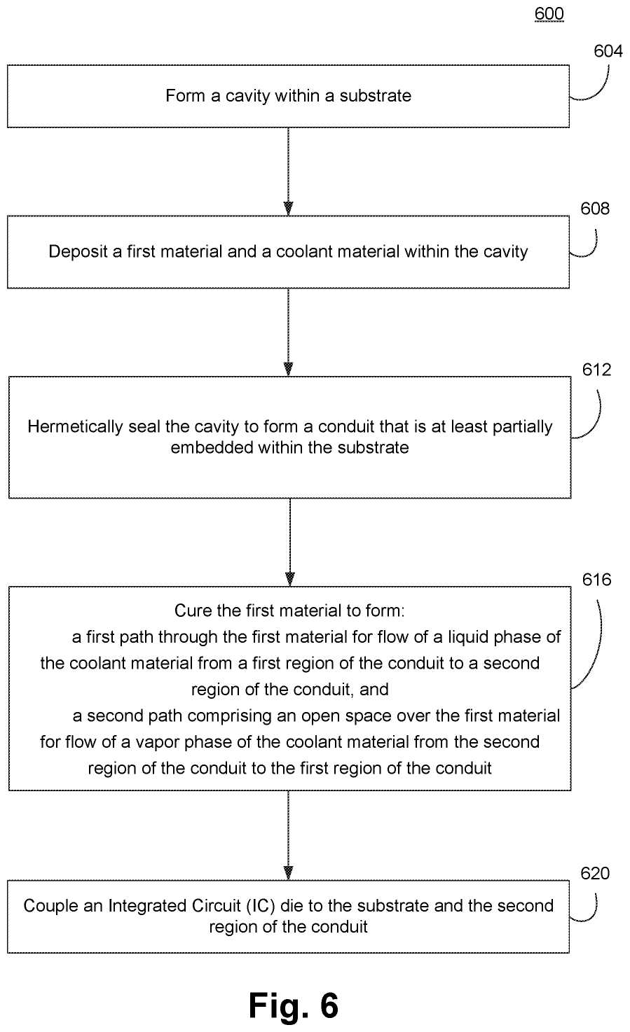

FIG. 6 illustrates a flowchart depicting a method 600 for forming a semiconductor device package structure (e.g., any of the packages 100, 300a-300e discussed herein) that includes a heat pipe device embedded at least in part within a substrate, e.g., to cool a component coupled to the substrate, according to some embodiments. Although the blocks in the flowchart with reference to FIG. 6 are shown in a particular order, the order of the actions can be modified. Thus, the illustrated embodiments can be performed in a different order, and some actions/blocks may be performed in parallel. Some of the blocks and/or operations listed in FIG. 6 may be optional in accordance with certain embodiments. The numbering of the blocks presented is for the sake of clarity and is not intended to prescribe an order of operations in which the various blocks must occur.

The method 600 includes, at 604, forming a cavity (e.g., conduit 107) within a substrate (e.g., substrate 112), e.g., as discussed with respect to FIG. 4A-4G or 5A). At 608, a first material and a coolant material (e.g., the material 416 of FIG. 4H, or the material 516 of FIG. 5B) is deposited within the cavity.

In some embodiments, depositing the first material and the coolant material within the cavity includes printing uncured material (e.g., the material 416 of FIG. 4H) within the cavity, where the uncured material includes the first material and the coolant material. In some embodiments, depositing the first material and the coolant material within the cavity includes laminating partially cured material (e.g., the material 516 of FIG. 5B) within the cavity, where the partially cured material includes the first material and the coolant material.

At 612, the cavity is hermetically sealed to form a conduit that is at least partially embedded within the substrate, e.g., as discussed with respect to FIG. 4I. At 616, the first material is cured to form: a first path through the first material for flow of a liquid phase of the coolant material from a first region of the conduit to a second region of the conduit, and a second path comprising an open space over the first material for flow of a vapor phase of the coolant material from the second region of the conduit to the first region of the conduit, e.g., as discussed with respect to FIG. 4J. At 620, an Integrated Circuit (IC) die (e.g., component 140) is coupled to the substrate and the second region of the conduit, e.g., as discussed with respect to FIG. 4L.

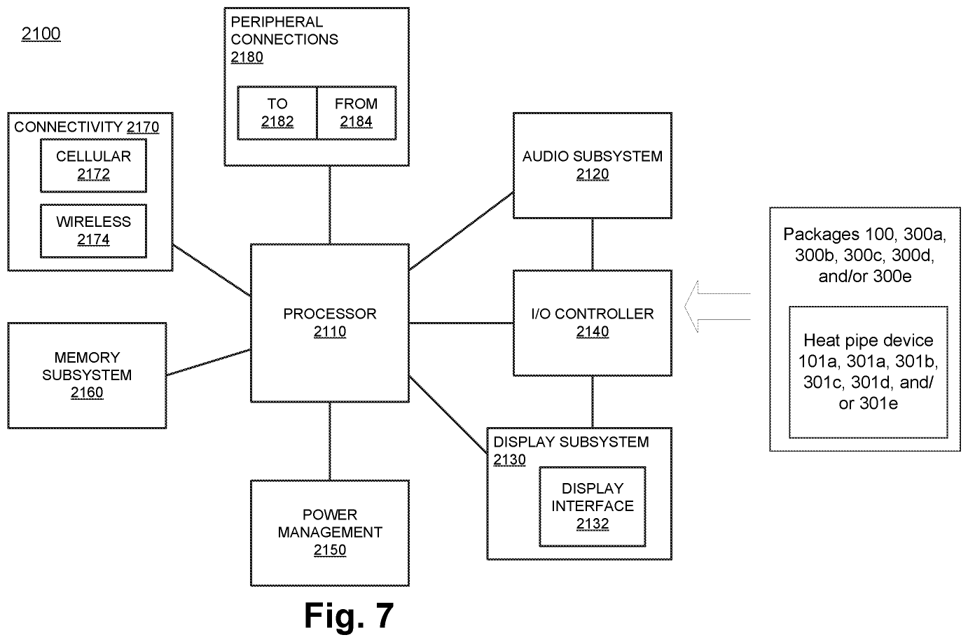

FIG. 7 illustrates a computer system, a computing device or a SoC (System-on-Chip) 2100, where one or more components of the computing device 2100 are included in a semiconductor package (e.g., any of the semiconductor packages discussed herein, such as packages 100, 300a, 300b, 300c, 300d, and/or 300e) that includes a heat pipe device (e.g., heat pipe device 101, 301a-301e) embedded at least in part within a substrate, e.g., to cool a component coupled to (or embedded within) the substrate, according to some embodiments. It is pointed out that those elements of FIG. 7 having the same reference numbers (or names) as the elements of any other figure can operate or function in any manner similar to that described, but are not limited to such.

In some embodiments, computing device 2100 represents an appropriate computing device, such as a computing tablet, a mobile phone or smart-phone, a laptop, a desktop, an IOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100. In one embodiment, computing device 2100 includes a clock generation subsystem to generate a clock signal.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, one or more components of the computing device 2100 may be included in one or more IC dies (e.g., components 140, 340a, 340b, 340c, 340d, 340e, etc.), discussed with respect to FIGS. 1A-6. For example, the processor 2110 and/or a memory of the memory subsystem 2160 is included in any of the components 140, 340a, 340b, 340c, 340d, 340e. The components 140, 340a, 340b, 340c, 340d, 340e are included in a semiconductor device package (e.g., any of packages 100, 300a, 300b, 300c, 300d, and/or 300e of FIGS. 1A-6) of the computing device 2100. Thus, one or more of the packages 100, 300a, 300b, 300c, 300d, and/or 300e may be included in the computing device 2100. The packages may include a heat pipe device (e.g., any of the heat pipe devices 101a, 301a, 301b, 301c, 301d, and/or 301e) embedded at least in part within a substrate, e.g., to cool the component coupled to the substrate, as discussed herein with respect to FIGS. 1A-6.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

### Example 1

A semiconductor device package structure comprising: a substrate; one or more dies coupled to the substrate; and a heat pipe device, wherein: the heat pipe device comprises a conduit at least partially embedded within the substrate, and the heat pipe device has a first region coupled to the one or more dies, and the conduit comprises: a first path for flow of vapor from the first region to an opposing second region; and a second path for flow of liquid from the second region to the first region.

### Example 2

The semiconductor package structure of example 1 or any other examples, wherein the heat pipe device comprises a heat sink coupled to the second region of the conduit.

### Example 3

The semiconductor package structure of example 1 or any other examples, wherein: the conduit includes material comprising pores; and the second path comprises the material, and the liquid is to flow through at least some of the pores.

### Example 4

The semiconductor package structure of example 3 or any other examples, wherein the material comprises one or both of: metal alkoxide, or polymer.

### Example 5

The semiconductor package structure of example 3 or any other examples, wherein: the first path comprises an open space within the conduit over the material.

### Example 6

The semiconductor package structure of example 1 or any other examples, wherein the liquid comprises one or more of: Water, Isopropyl Alcohol, Ethanol, Methanol, Acetone, or Diethyl Ether.

### Example 7

The semiconductor package structure of example 1 or any other examples, wherein: at least a section of the one or more dies is embedded within a first level of the substrate; and at least a section of the conduit is embedded within the first level substrate.

### Example 8

The semiconductor package structure of example 1 or any other examples, wherein: the substrate comprises a first side and an opposing second side; the one or more dies are coupled to the first side of the substrate through first one or more interconnect structures; the heat pipe device comprises a heat sink coupled to the first side of the substrate, and to the second region of the conduit; and the semiconductor package structure comprises second one or more interconnect structures coupled to the second side of the substrate.

### Example 9

The semiconductor package structure of example 8 or any other examples, further comprising: third one or more interconnect structures to couple the first one or more interconnect structures and the second one or more interconnect structures, wherein the one or more sidewalls of the conduit comprise a first material, and the third one or more interconnect structures comprises the first material.

### Example 10

The semiconductor package structure of example 1 or any other examples, wherein one or more sidewalls of the conduit are either electrically floating or electrically grounded.

### Example 11

The semiconductor package structure of example 1 or any other examples, wherein the first region of the conduit is coupled to the one or more dies through one or more of: thermally conductive underfill material having higher thermal conductivity than a dielectric layer of the substrate, or one or more interconnect structures.

### Example 12

The semiconductor package structure of example 1 or any other examples, wherein, during an operation of the one or more dies, a temperature of the first region of the conduit is equal to, or higher than, a temperature of the second region of the conduit.

### Example 13

The semiconductor package structure of example 1 or any other examples, wherein at least a first side and a second side of one or more sidewalls of the conduit is in contact with the substrate.

### Example 14

The semiconductor package structure of example 1 or any other examples, wherein the conduit is fully embedded within the substrate with no section of the conduit is exposed outside the substrate.

### Example 15

A system comprising: a substrate having a first side and an opposing second side; one or more dies coupled to the first side of the substrate; a circuit board coupled to the second side of the substrate; and a heat pipe device, wherein the heat pipe device comprises a conduit at least partially embedded within the substrate and having a first region coupled to the one or more dies, and wherein the conduit comprises: a first path for flow of vapor from the first region to an opposing second region, and a second path for flow of liquid from the second region to the first region.

### Example 16

The system of example 15 or any other examples, further comprising: a power supply system to supply power to at least one of the one or more dies; a wireless interface to facilitate the system to communicate with another system; a memory to store instructions; and a processor to execute the instructions, wherein at least one of the memory or the processor is included in at least one of the one or more dies.

### Example 17

The system of example 15 or any other examples, wherein: the conduit is hermetically sealed by one or more sidewalls; the one or more sidewalls of the conduit comprise copper; the one or more sidewalls of the conduit are either electrically floating or electrically grounded, wherein the conduit includes material comprising pores, and wherein the second path comprises the material, and the liquid is to flow through at least some of the pores of the material.

### Example 18

A method comprising: forming a cavity within a substrate; depositing a first material and a coolant material within the cavity; hermetically sealing the cavity to form a conduit that is at least partially embedded within the substrate; curing the first material to form: a first path through the first material for flow of a liquid phase of the coolant material from a first region of the conduit to a second region of the conduit, and a second path comprising an open space over the first material for flow of a vapor phase of the coolant material from the second region of the conduit to the first region of the conduit; and coupling an Integrated Circuit (IC) die to the substrate and the second region of the conduit.

### Example 19

The method of example 18 or any other examples, further comprising: forming a heat sink coupled to the first region of the conduit.

### Example 20

The method of example 18 or any other examples, wherein depositing the first material and the coolant material within the cavity comprises at least one of: printing uncured material within the cavity, the uncured material comprising the first material and the coolant material; or laminating partially cured material within the cavity, the partially cured material comprising the first material and the coolant material.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. A semiconductor device package structure comprising:
a substrate;
one or more dies coupled to the substrate; and
a heat pipe device, wherein:
the heat pipe device comprises a conduit at least partially embedded within the substrate, and the heat pipe device has a first region coupled to the one or more dies, and
the conduit comprises:
a first path for flow of vapor from the first region to an opposing second region; and
a second path for flow of liquid from the second region to the first region.

2. The semiconductor package structure of claim 1, wherein the heat pipe device comprises a heat sink coupled to the second region of the conduit.

3. The semiconductor package structure of claim 1, wherein:
the conduit includes material comprising pores; and
the second path comprises the material, and the liquid is to flow through at least some of the pores.

4. The semiconductor package structure of claim 3, wherein the material comprises one or both of: metal alkoxide, or polymer.

5. The semiconductor package structure of claim 3, wherein:
the first path comprises an open space within the conduit over the material.

6. The semiconductor package structure of claim 1, wherein the liquid comprises one or more of: Water, Isopropyl Alcohol, Ethanol, Methanol, Acetone, or Diethyl Ether.

7. The semiconductor package structure of claim 1, wherein:
at least a section of the one or more dies is embedded within a first level of the substrate; and
at least a section of the conduit is embedded within the first level substrate.

8. The semiconductor package structure of claim 1, wherein:
the substrate comprises a first side and an opposing second side;
the one or more dies are coupled to the first side of the substrate through first one or more interconnect structures;
the heat pipe device comprises a heat sink coupled to the first side of the substrate, and to the second region of the conduit; and
the semiconductor package structure comprises second one or more interconnect structures coupled to the second side of the substrate.

9. The semiconductor package structure of claim 8, further comprising:
third one or more interconnect structures to couple the first one or more interconnect structures and the second one or more interconnect structures,
wherein the one or more sidewalls of the conduit comprise a first material, and the third one or more interconnect structures comprises the first material.

10. The semiconductor package structure of claim 1, wherein one or more sidewalls of the conduit are either electrically floating or electrically grounded.

11. The semiconductor package structure of claim 1, wherein the first region of the conduit is coupled to the one or more dies through one or more of: thermally conductive underfill material having higher thermal conductivity than a dielectric layer of the substrate, or one or more interconnect structures.

12. The semiconductor package structure of claim 1, wherein, during an operation of the one or more dies, a temperature of the first region of the conduit is equal to, or higher than, a temperature of the second region of the conduit.

13. The semiconductor package structure of claim 1, wherein at least a first side and a second side of one or more sidewalls of the conduit is in contact with the substrate.

14. The semiconductor package structure of claim 1, wherein the conduit is fully embedded within the substrate with no section of the conduit is exposed outside the substrate.

15. A system comprising:
a substrate having a first side and an opposing second side;
one or more dies coupled to the first side of the substrate;
a circuit board coupled to the second side of the substrate; and
a heat pipe device,
wherein the heat pipe device comprises a conduit at least partially embedded within the substrate and having a first region coupled to the one or more dies, and
wherein the conduit comprises: a first path for flow of vapor from the first region to an opposing second region, and a second path for flow of liquid from the second region to the first region.

16. The system of claim 15, further comprising:
a power supply system to supply power to at least one of the one or more dies;
a wireless interface to facilitate the system to communicate with another system;
a memory to store instructions; and
a processor to execute the instructions, wherein at least one of the memory or the processor is included in at least one of the one or more dies.

17. The system of claim 15, wherein:
the conduit is hermetically sealed by one or more sidewalls;
the one or more sidewalls of the conduit comprise copper;
the one or more sidewalls of the conduit are either electrically floating or electrically grounded,
wherein the conduit includes material comprising pores, and
wherein the second path comprises the material, and the liquid is to flow through at least some of the pores of the material.

18. A method comprising:
forming a cavity within a substrate;
depositing a first material and a coolant material within the cavity;
hermetically sealing the cavity to form a conduit that is at least partially embedded within the substrate;
curing the first material to form:
a first path through the first material for flow of a liquid phase of the coolant material from a first region of the conduit to a second region of the conduit, and
a second path comprising an open space over the first material for flow of a vapor phase of the coolant material from the second region of the conduit to the first region of the conduit; and
coupling an Integrated Circuit (IC) die to the substrate and the second region of the conduit.

19. The method of claim 18, further comprising:
forming a heat sink coupled to the first region of the conduit.

20. The method of claim 18, wherein depositing the first material and the coolant material within the cavity comprises at least one of:
printing uncured material within the cavity, the uncured material comprising the first material and the coolant material; or
laminating partially cured material within the cavity, the partially cured material comprising the first material and the coolant material.
